(19) United States
(12) Patent Application Publication
(10) Pub. No.: US 2026/0090091 A1
(43) Pub. Date: Mar. 26, 2026

(54) L-SHAPED STACKED SEMICONDUCTOR ARCHITECTURE

(71) Applicant: International Business Machines Corporation, Armonk, NY (US)

(72) Inventors: Kishwar Mashooq, Albany, NY (US); Shay Reboh, Guilderland, NY (US); Utkarsh Bajpai, Suffern, NY (US)

(21) Appl. No.: 18/890,998

(22) Filed: Sep. 20, 2024

(51) Int. Cl. H01L 27/092; H01L 29/06; H01L 29/10; H01L 29/417; H01L 29/423; H01L 29/66; H01L 29/775; H01L 29/786

(52) U.S. Cl. CPC H10D 84/856; H10D 30/6729; H10D 62/235; H10D 30/014; H10D 30/43; H10D 30/6735; H10D 30/6757; H10D 62/121

(57) ABSTRACT

A semiconductor device includes a first transistor device including a first plurality of channel layers and a first source/drain region and a second transistor device comprising a second plurality of channel layers and a second source/drain region, where the first plurality of channel layers are vertically stacked with the second plurality of channel layers and the first source/drain region is laterally offset from the second source/drain region.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Illustrative embodiments of the present application include techniques for use in semiconductor manufacture. In an illustrative embodiment, a semiconductor device includes a first transistor device including a first plurality of channel layers and a first source/drain region and a second transistor device comprising a second plurality of channel layers and a second source/drain region, where the first plurality of channel layers are vertically stacked with the second plurality of channel layers and the first source/drain region is laterally offset from the second source/drain region.

In another illustrative embodiment, a semiconductor device includes an L-shaped stacked transistor architecture comprising a bottom transistor device having a bottom source/drain region and a top transistor device having a top source/drain region, wherein the bottom source/drain region is laterally offset from the top source/drain region.

In another exemplary embodiment, a method includes forming a first plurality of channel layers corresponding to a first transistor device and a second plurality of channel layers corresponding to a second transistor device, where the second plurality of channel layers is vertically stacked on the first plurality of channel layers, and wherein the first plurality of channel layers is wider than the second plurality of channel layers. The method includes forming a first source/drain region along at least a portion of the first plurality of channel layers and forming a second source/drain region that is above and laterally offset from the first source/drain region.

Other embodiments will be described in the following detailed description of embodiments, which is to be read in conjunction with the accompanying figures.

### BRIEF DESCRIPTION OF THE DRAWINGS

FIG. 1 depicts a top view of a semiconductor structure with lines A, B, C, and D on which the cross-sectional views of FIGS. 2A-11C are based, according to an illustrative embodiment.

FIG. 2A depicts a first cross-sectional view corresponding to line A in FIG. 1 illustrating the semiconductor structure of FIG. 1 during an intermediate step of a method of fabricating a nanosheet transistor structure, according to an illustrative embodiment.

FIG. 2B depicts a second cross-sectional view corresponding to line B in FIG. 1 illustrating the semiconductor structure of FIG. 1 during the intermediate step of the method of fabricating the nanosheet transistor structure, according to an illustrative embodiment.

FIG. 2C depicts a second cross-sectional view corresponding to line C in FIG. 1 illustrating the semiconductor structure of FIG. 1 during the intermediate step of the method of fabricating the nanosheet transistor structure, according to an illustrative embodiment.

FIG. 2D depicts a second cross-sectional view corresponding to line D in FIG. 1 illustrating the semiconductor structure of FIG. 1 during the intermediate step of the method of fabricating the nanosheet transistor structure, according to an illustrative embodiment.

FIG. 3A depicts a first cross-sectional view corresponding to line A in FIG. 1 following recessing of a dielectric protection layer, according to an illustrative embodiment.

FIG. 3B depicts a first cross-sectional view corresponding to line B in FIG. 1 following the recessing of the dielectric protection layer, according to an illustrative embodiment.

FIG. 3C depicts a second cross-sectional view corresponding to line C in FIG. 1 following the recessing of the dielectric protection layer, according to an illustrative embodiment.

FIG. 3D depicts a second cross-sectional view corresponding to line D in FIG. 1 following the recessing of the dielectric protection layer, according to an illustrative embodiment.

FIG. 4A depicts a first cross-sectional view corresponding to line A in FIG. 1 following hardmask (HM) layer removal and formation of a bottom source/drain region, according to an illustrative embodiment.

FIG. 4B depicts a first cross-sectional view corresponding to line B in FIG. 1 following the HM layer removal and formation of the bottom source/drain region, according to an illustrative embodiment.

FIG. 4C depicts a second cross-sectional view corresponding to line C in FIG. 1 following the HM layer removal and formation of the bottom source/drain region, according to an illustrative embodiment.

FIG. 4D depicts a second cross-sectional view corresponding to line D in FIG. 1 following the HM layer removal and formation of the bottom source/drain region, according to an illustrative embodiment.

FIG. 5A depicts a first cross-sectional view corresponding to line A in FIG. 1 following a dielectric fill process, according to an illustrative embodiment.

FIG. 5B depicts a first cross-sectional view corresponding to line B in FIG. 1 following the dielectric fill process, according to an illustrative embodiment.

FIG. 5C depicts a second cross-sectional view corresponding to line C in FIG. 1 following the dielectric fill process, according to an illustrative embodiment.

FIG. 5D depicts a second cross-sectional view corresponding to line D in FIG. 1 following the dielectric fill process, according to an illustrative embodiment.

FIG. 6A depicts a first cross-sectional view corresponding to line A in FIG. 1 following recessing of the dielectric protection layer, according to an illustrative embodiment.

FIG. 6B depicts a first cross-sectional view corresponding to line B in FIG. 1 following the recessing of the dielectric protection layer, according to an illustrative embodiment.

FIG. 6C depicts a second cross-sectional view corresponding to line C in FIG. 1 following the recessing of the dielectric protection layer, according to an illustrative embodiment.

FIG. 6D depicts a second cross-sectional view corresponding to line D in FIG. 1 following the recessing of the dielectric protection layer, according to an illustrative embodiment.

FIG. 7A depicts a first cross-sectional view corresponding to line A in FIG. 1 following formation of a blocking spacer layer and an oxide layer, according to an illustrative embodiment.

FIG. 7B depicts a first cross-sectional view corresponding to line B in FIG. 1 following formation of the blocking spacer layer and the oxide layer, according to an illustrative embodiment.

FIG. 7C depicts a second cross-sectional view corresponding to line C in FIG. 1 following formation of the blocking spacer layer and the oxide layer, according to an illustrative embodiment.

FIG. 7D depicts a second cross-sectional view corresponding to line D in FIG. 1 following formation of the blocking spacer layer and the oxide layer, according to an illustrative embodiment.

FIG. 8A depicts a first cross-sectional view corresponding to line A in FIG. 1 following blocking spacer layer removal, according to an illustrative embodiment.

FIG. 8B depicts a first cross-sectional view corresponding to line B in FIG. 1 following the blocking spacer layer removal, according to an illustrative embodiment.

FIG. 8C depicts a second cross-sectional view corresponding to line C in FIG. 1 following the blocking spacer layer removal, according to an illustrative embodiment.

FIG. 8D depicts a second cross-sectional view corresponding to line D in FIG. 1 following the blocking spacer layer removal, according to an illustrative embodiment.

FIG. 9A depicts a first cross-sectional view corresponding to line A in FIG. 1 following formation of a top source/drain region, according to an illustrative embodiment.

FIG. 9B depicts a first cross-sectional view corresponding to line B in FIG. 1 following the formation of the top source/drain region, according to an illustrative embodiment.

FIG. 9C depicts a second cross-sectional view corresponding to line C in FIG. 1 following the formation of the top source/drain region, according to an illustrative embodiment.

FIG. 9D depicts a second cross-sectional view corresponding to line D in FIG. 1 following the formation of the top source/drain region, according to an illustrative embodiment.

FIG. 10A depicts a first cross-sectional view corresponding to line A in FIG. 1 following further processing steps, according to an illustrative embodiment.

FIG. 10B depicts a first cross-sectional view corresponding to line B in FIG. 1 following the further processing steps, according to an illustrative embodiment.

FIG. 10C depicts a second cross-sectional view corresponding to line C in FIG. 1 following the further processing steps, according to an illustrative embodiment.

FIG. 10D depicts a second cross-sectional view corresponding to line D in FIG. 1 following the further processing steps, according to an illustrative embodiment.

FIGS. 11A-11C depict respective cross-sectional views corresponding to line D in FIG. 1 for alternative configurations of the semiconductor structure in accordance with illustrative embodiments.

### DETAILED DESCRIPTION

Illustrative embodiments are described herein in the context of illustrative methods for configuring stacked semiconductor structures with opposite polarity transistors, along with illustrative apparatus, systems, and devices formed using such methods. However, it is to be understood that embodiments described herein are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment,” as well as any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. In FinFET structures, the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7nm and beyond. A general process flow for formation of a nanosheet stack involves selectively removing sacrificial layers, which may be formed of silicon germanium (SiGe), between sheets of channel material, which may be formed of silicon (Si).

For continued scaling (for example, to 2.5 nm and beyond), next generation stacked FET (SFET) devices may be used. Next-generation SFET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation SFET structures provide improved track height scaling, leading to structural gains (for example, such as 30-40% structural gains for different types of devices, such as logic devices, static random-access memory (SRAM) devices, etc.). In next-generation SFET structures, n-type, and p-type nanowires or nanosheets are stacked on each other, eliminating n-to-p separation bottlenecks, and reducing the device area footprint. There is, however, a continued desire for further scaling and reducing the size of FETs.

As discussed above, various techniques may be used to reduce the size of FETs, including using fin-shaped channels in FinFET devices, using stacked nanosheet channels formed over a semiconductor substrate, and using next-generation SFET devices.

With the aggressive scaling of stacked FET structures, it is often challenging to form a bottom source/drain region in a high aspect ratio canyon. At least some embodiments described herein address such challenges by forming a bottom source/drain region at a stepped portion of an L-shaped stacked FET architecture, thereby eliminating the need for an additional blocking spacer layer when forming the bottom source/drain region. Such embodiments can improve FET capacitance and scalability (e.g., to be scalable under 48 nm contact poly pitch (CPP)), while also simplifying the integration process.

Although embodiments described herein are discussed in connection with nanosheet stacks, the embodiments are not necessarily limited thereto and may similarly apply to nanowire stacks.

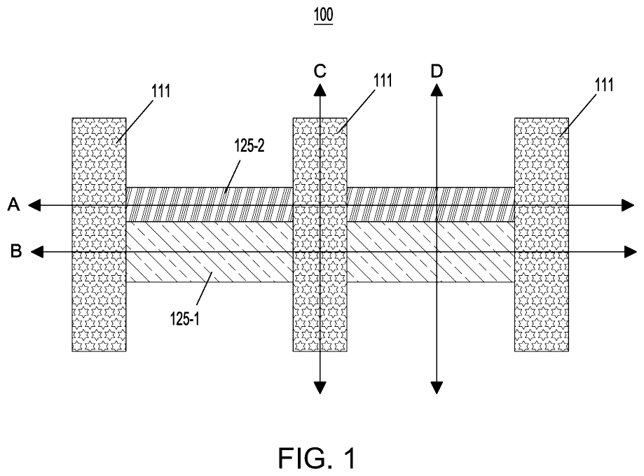

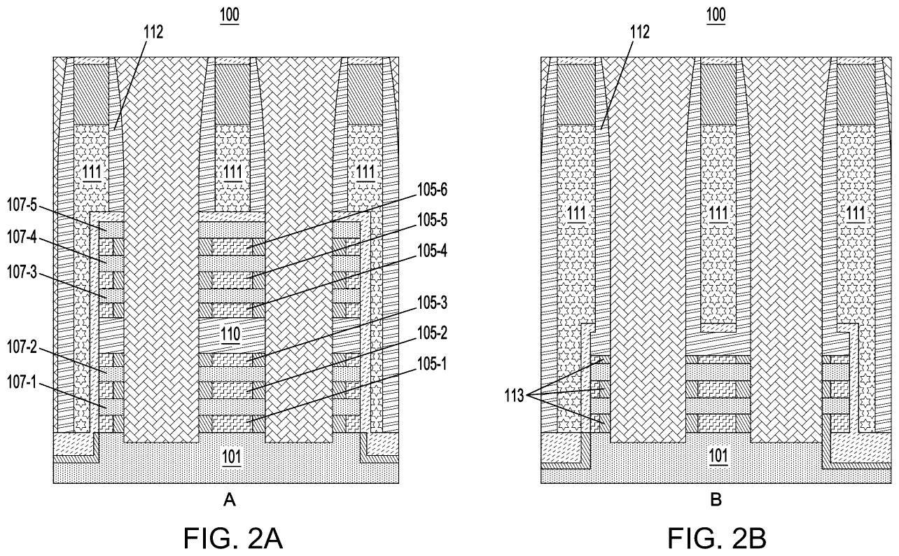

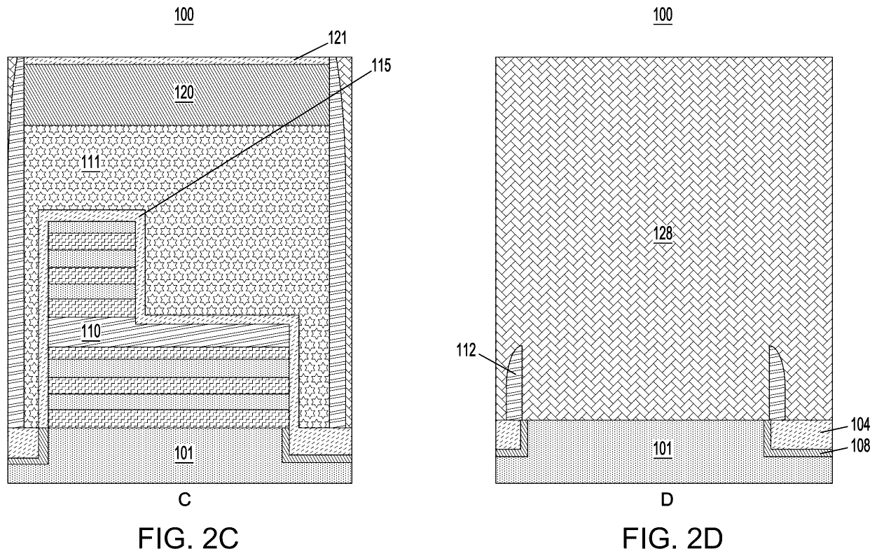

Referring to FIG. 1 and to the cross-sectional views in FIGS. 2A-2D, which respectively correspond to the lines A, B, C, and D in FIG. 1, a semiconductor structure 100 includes a first transistor active area 125-1 and a second transistor active area 125-2. In some embodiments, the first transistor active area 125-1 is associated with a first plurality of source/drain regions, while the second transistor active area 125-2 can be associated with a second plurality of source/drain regions. In such embodiments, the first plurality of source/drain regions may have a different doping type (e.g., N+) than the second plurality of source/drain regions (e.g., P+), as described in more detail elsewhere herein.

The semiconductor structure 100 also includes a stacked structure comprising sacrificial layers 105-1, 105-2, 105-3, 105-4, 105-5, and 105-6 (collectively “sacrificial layers 105”) and channel layers 107-1, 107-2, 107-3, 107-4, and 107-5 (collectively “channel layers 107”). In an illustrative embodiment, the sacrificial layers 105 comprise SiGe and the channel layers 107 comprise silicon. The stacked structure also includes a middle dielectric isolation (MDI) layer 110. The MDI layer 110 may comprise, for example, silicon oxide (SiOₓ) (where x is for example, 2, 1.99 or 2.01), silicon oxycarbide (SiOC), silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof.

While six sacrificial layers 105 and five channel layers 107 are shown, the embodiments described herein are not necessarily limited to the shown number of sacrificial layers 105 and channel layers 107. There may be more or less layers in the same alternating configuration depending on design constraints. The sacrificial layers 105, as described further herein, are eventually removed, and replaced by gate structures.

The sacrificial layers 105 and the channel layers 107 are epitaxially grown on a semiconductor substrate 101. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The semiconductor substrate 101 may be formed of any suitable semiconductor structure, including various silicon-containing materials including but not limited to Si, SiGe, silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), and zinc selenide (ZnSe).

As used herein, “frontside” or “first side” refers to a side on top of the semiconductor substrate 101 and/or in front of, on top of or in an upward direction from the stacked gate and channel layers of the transistors in the orientation shown in the cross-sectional figures. As used herein, “backside” or “second side” refers to a side below the semiconductor substrate 101 and/or behind, below, or in a downward direction from the stacked gate and channel layers of the transistors in the orientation shown in the cross-sectional figures (for example, opposite the “frontside”).

Isolation regions 104 (for example, shallow trench isolation (STI) regions) comprising dielectric material fill in recessed portions of the semiconductor substrate 101 between the nanosheet stacks of sacrificial layers 105 and the channel layers 107. A corresponding liner layer 108 is also formed between the isolation regions 104 and the semiconductor substrate 101. The liner layer 108 may be formed of SiN or another suitable material such as SiBCN, SiCOH, SiNCH, etc. The dielectric material may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), and combinations thereof.

A protective liner 115 is formed on sidewalls of the sacrificial layers 105 and the channel layers 107, and on the top surfaces of the uppermost sacrificial layers 105, as shown in FIG. 2C, for example. The protective liner 115 may be formed of SiN, SiO2, or another suitable material such as SiBCN, SiCOH, SiNCH, etc.

Inner spacers 113 are formed between portions of the top and bottom surfaces of the MDI layer 110, and on sides of the stacked structures of the sacrificial layers 105 and the channel layers 107, as shown. Due to, for example, germanium in the sacrificial layers 105, lateral etching of the sacrificial layers 105 can be performed selective to the channel layers 107, such that the side portions of the sacrificial layers 105 can be removed to create vacant areas to be filled in by the inner spacers 113. The material of the inner spacers 113 can comprise, but is not necessarily limited to, a nitride, such as, SiN, SiON, SiCN, BN, SiBN, SiBCN or SiOCN.

Dummy gate portions 111 are formed on and around the protective liner 115 of the nanosheet stacks of the sacrificial layers 105 and channel layers 107. The dummy gate portions 111 include, but are not necessarily limited to, an amorphous silicon (a-Si) layer. The dummy gate portions 111 are formed using any suitable deposition techniques, such as chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), followed by a planarization step such as a chemical mechanical planarization (CMP) process.

Gate spacers 112 are positioned on opposite lateral sides of the dummy gate portions 111. In an illustrative embodiment, the gate spacers 112 are formed from the same or similar material to that of the inner spacers 113.

Hardmask (HM) layers 120 and 121 are formed on the dummy gate portions 111. The HM layer 120 comprises, for example, a nitride such as SiN or other nitride material. The HM layer 121 can be formed of any suitable material such as oxide and/or nitride materials such as SiN, a multi-layer of SiN and SiO₂, or other suitable material.

A dielectric protection layer 128 is formed by depositing dielectric material on exposed portions of the semiconductor substrate 101 between the nanosheet stacks of the sacrificial layers 105 and channel layers 107. In some embodiments, a poly open CMP (POC) process is performed to remove excess portions of the dielectric protection layer 128 deposited on top of the HM layer 121 and gate spacers 112. In some embodiments, the dielectric material may comprise, for example, oxide and/or nitride materials such as SiN, a multi-layer of SiN and SiO₂, or other suitable material, and is deposited using deposition techniques such as, for example, CVD, PECVD, RFCVD, PVD, ALD, MBD, PLD, and/or LSMCD.

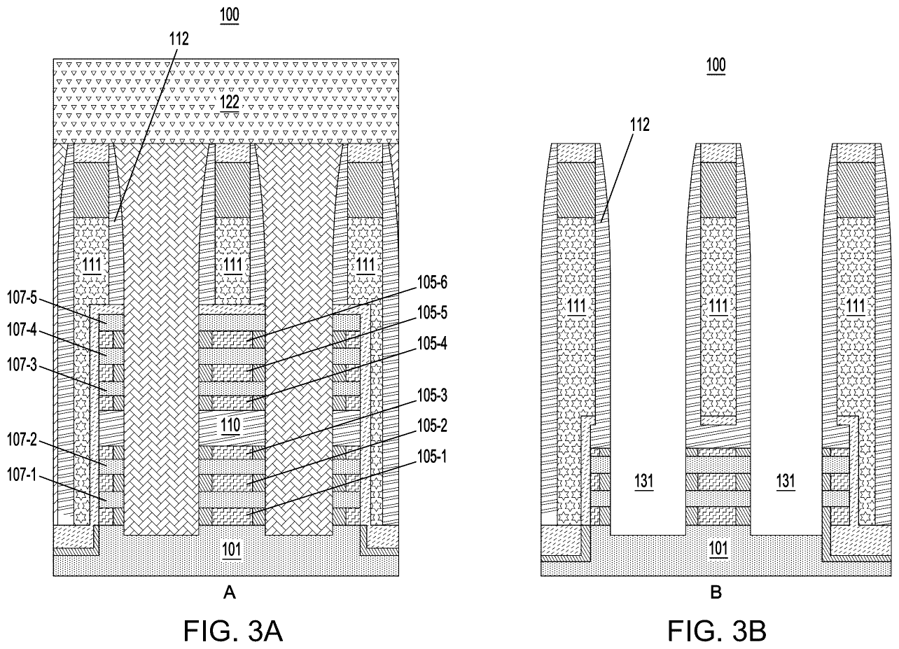

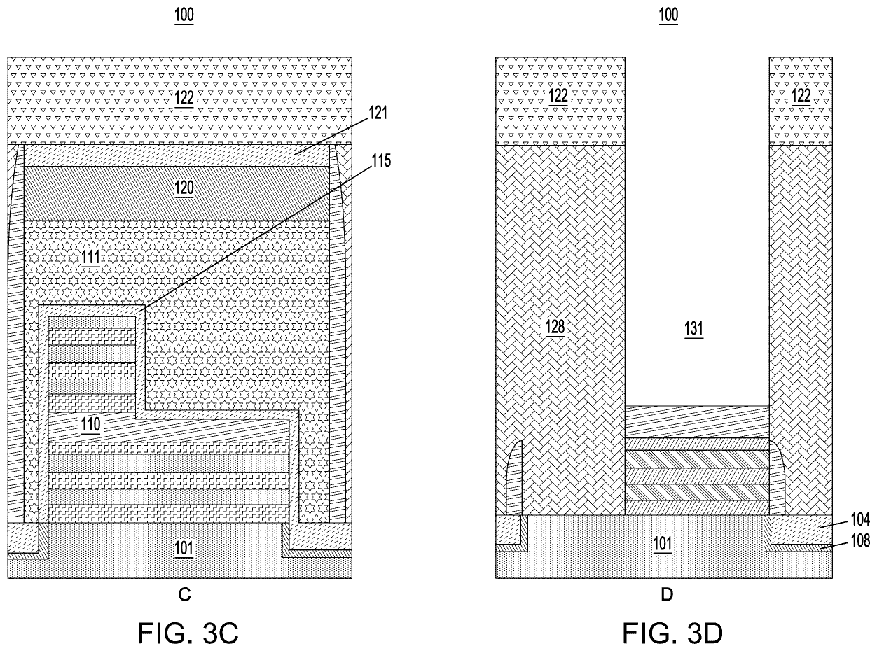

FIGS. 3A-3D show cross-sectional views of the semiconductor structure 100 following a recessing of the dielectric protection layer. The recessing includes forming a HM layer 122 on the top surfaces of the HM layer 121 and the dielectric protection layer 128 with openings corresponding to portions of the dielectric protection layer 128 that are to be removed. The HM layer 122 can comprise, for example, a nitride such as SiN or other nitride material. The portions of the dielectric protection layer 128 are then removed to form vacant areas 131. The portions of the dielectric protection layer 128 can be removed using, for example, a dry etching process using a reactive ion etching (RIE) or an ion beam etch (IBE) process, a wet chemical etching process or a combination of these etching processes. A dry etch may be performed using a plasma. Such wet or dry etch processes include, for example, IBE by Ar/CHF3 based chemistry.

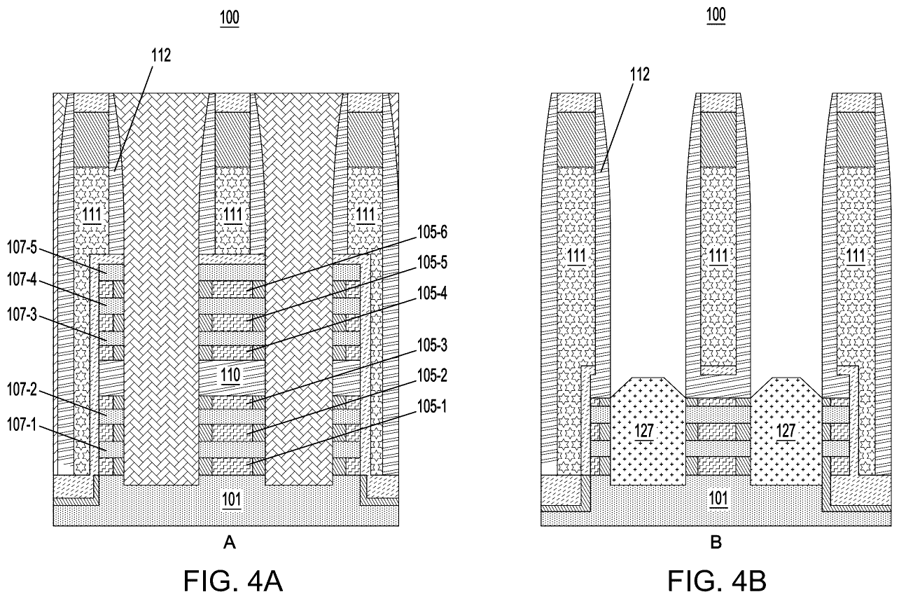

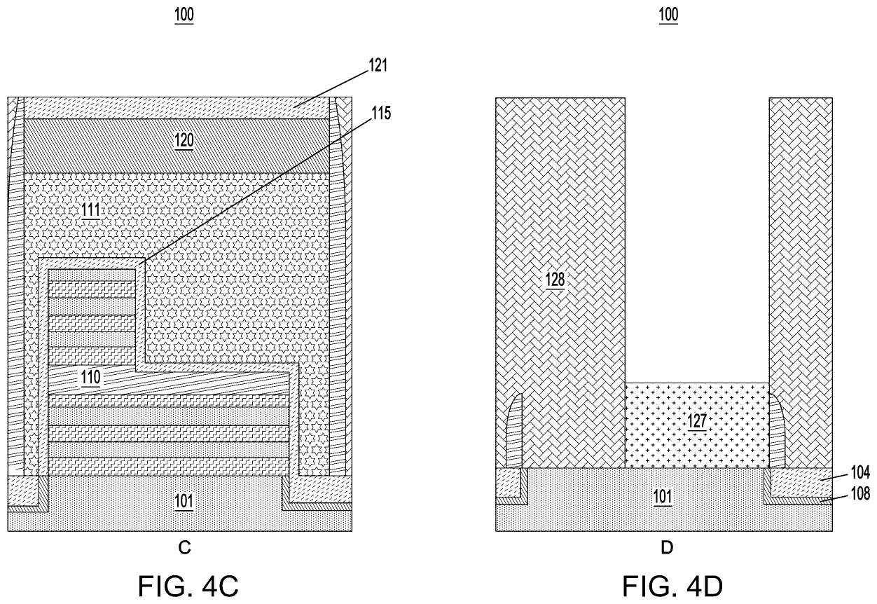

FIGS. 4A-4D show cross-sectional views corresponding to the semiconductor structure 100 following removal of the HM layer 122 and formation of a bottom source/drain region 127, according to an illustrative embodiment. The HM layer 122 can be removed using, for example, a plasma stripping process or a wet etch process. For example, the bottom source/drain region 127 can be epitaxially grown from the exposed surfaces of the channel layers 107 in the bottom portions of the vacant areas 131 as shown in FIGS. 4B and 4D.

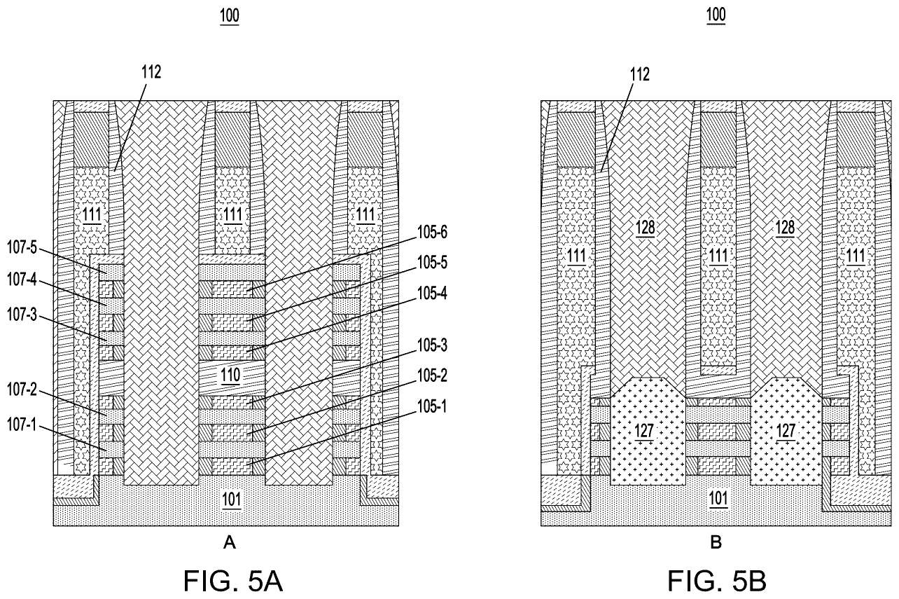

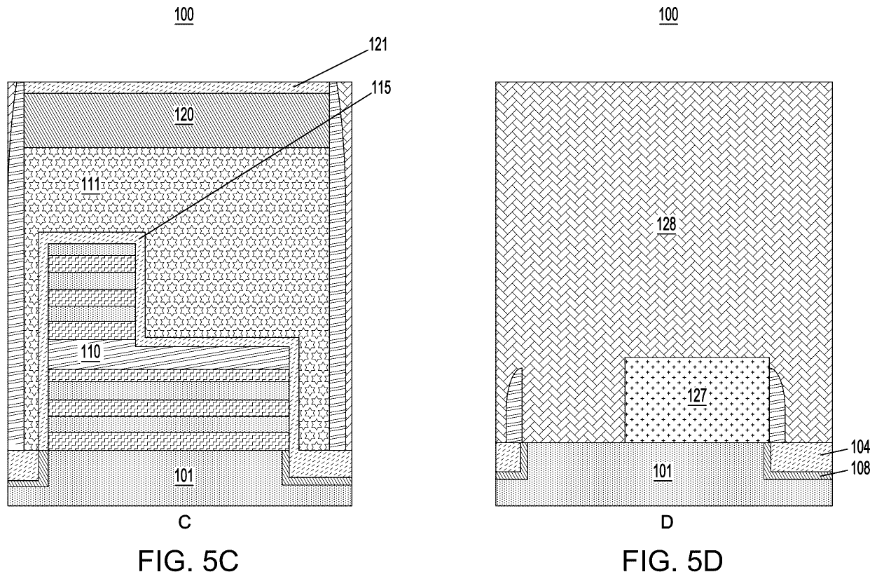

FIGS. 5A-5D show cross-sectional views corresponding to the semiconductor structure 100 following a dielectric fill process, according to an illustrative embodiment. The dielectric fill process includes filling remaining portions of the vacant areas 131 with dielectric material to backfill the dielectric protection layer 128. The dielectric fill process can use similar techniques and materials as described above for the dielectric protection layer 128.

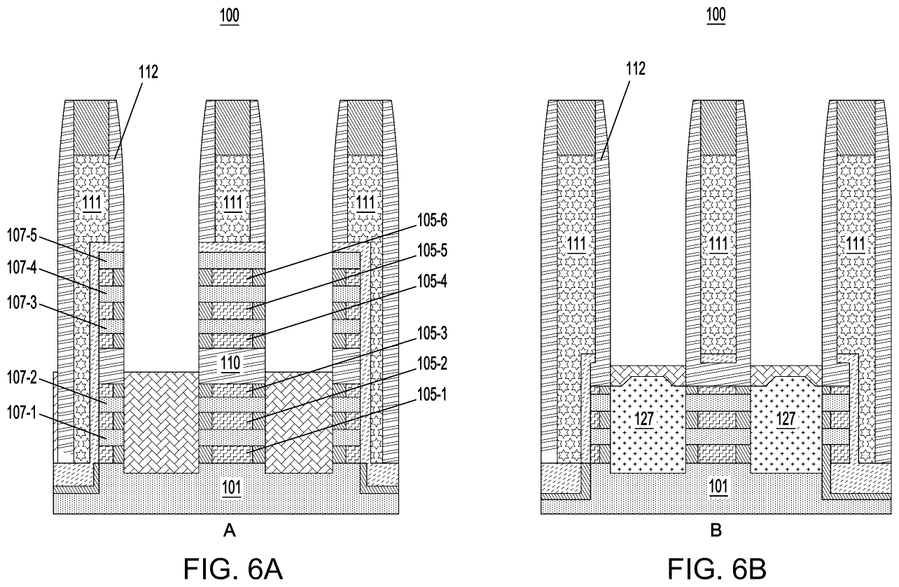

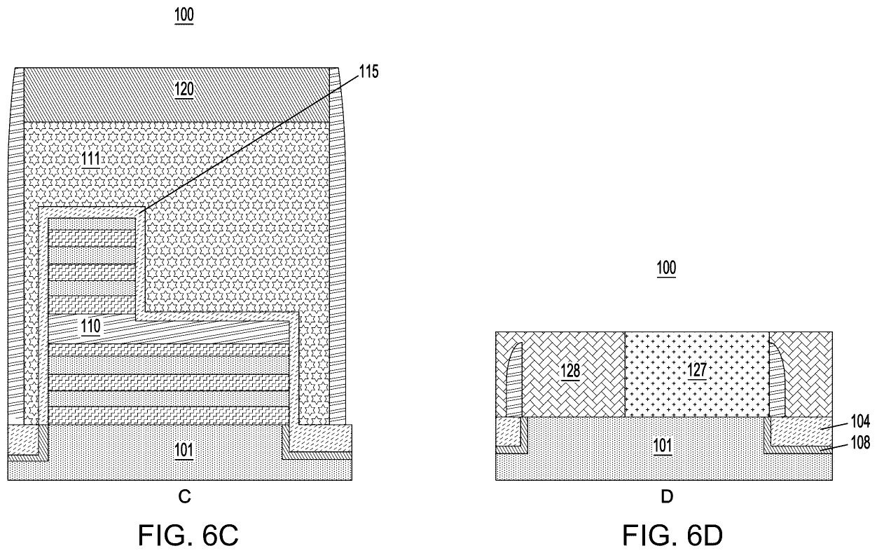

FIGS. 6A-6D depict cross-sectional views of the semiconductor structure 100 following additional recessing of the dielectric protection layer 128, according to an illustrative embodiment. The dielectric protection layer 128 is recessed down to a level corresponding to the top surface of the bottom source/drain region 127 using, for example, a dry etching process using a RIE or IBE process, a wet chemical etch process or a combination of these etching processes.

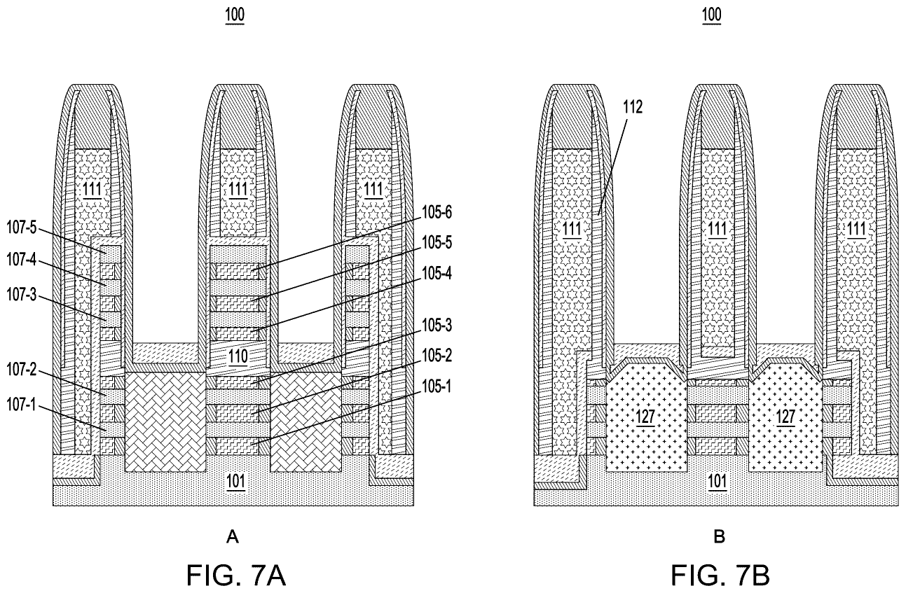

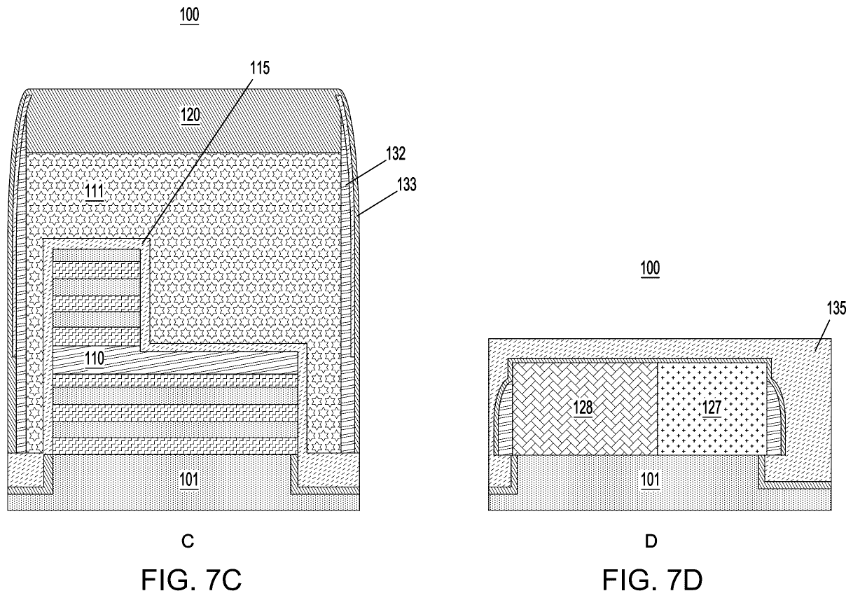

FIGS. 7A-7D depict cross-sectional views of the semiconductor structure 100 following formation of an oxide layer 132 and a blocking spacer layer 133, according to an illustrative embodiment. The oxide layer 132 can be deposited on the sidewalls of the gate spacers 112 down to a level corresponding to the bottom source/drain region 127. The oxide layer 132 can be applied using a CVD deposition process, for example. Portions of the dielectric protection layer 128 are removed, as shown in FIG. 7D.

The blocking spacer layer 133 can be formed of a nitride, such as SiN or other nitride material. The blocking spacer layer 133 covers the exposed surfaces of the oxide layer 132, the dielectric protection layer 128, the bottom source/drain region 127, and the gate spacers 112.

An inter-layer dielectric (ILD) layer 135 is formed to fill in vacant spaces on and around the blocking spacer layer 133 up to a level corresponding to the top surface of the MDI layer 110. The dielectric material can be deposited using deposition techniques such as, for example, CVD, PECVD, RFCVD, PVD, ALD, MBD, PLD, and/or LSMCD. In some embodiments, the ILD layer 135 can be formed using similar processes and materials as dielectric protection layer 128, for example.

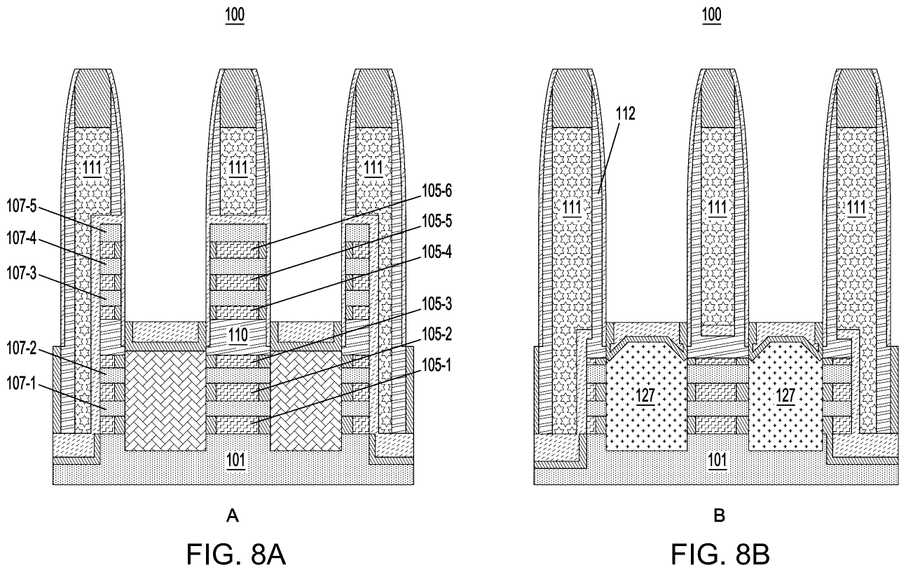

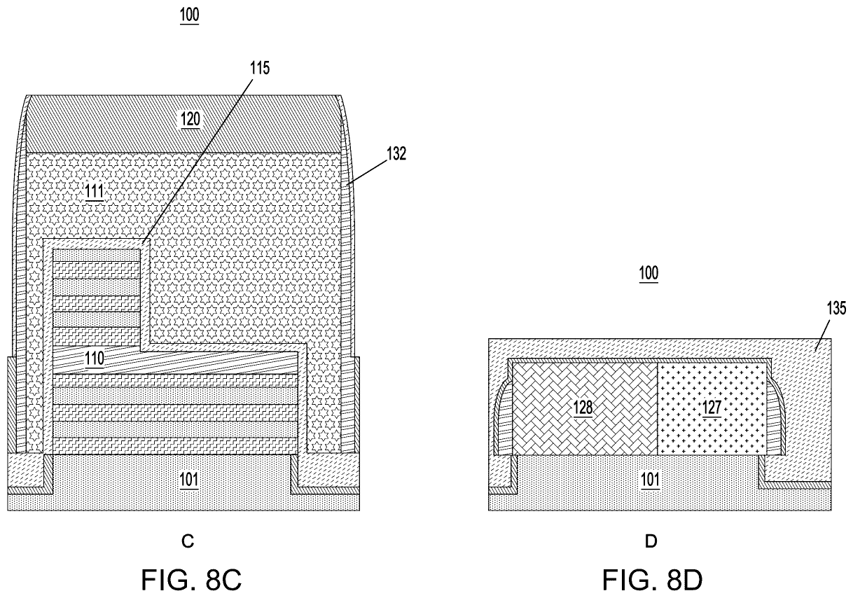

FIGS. 8A-8D depict cross-sectional views of the semiconductor structure 100 following removal of portions of the blocking spacer layer 133, according to an illustrative embodiment. The portions of the blocking spacer layer 133 above the top surface of the ILD layer 135 are removed using, for example, any suitable etch process, such as atomic layer etching (ALE), isotropic etching, etc.

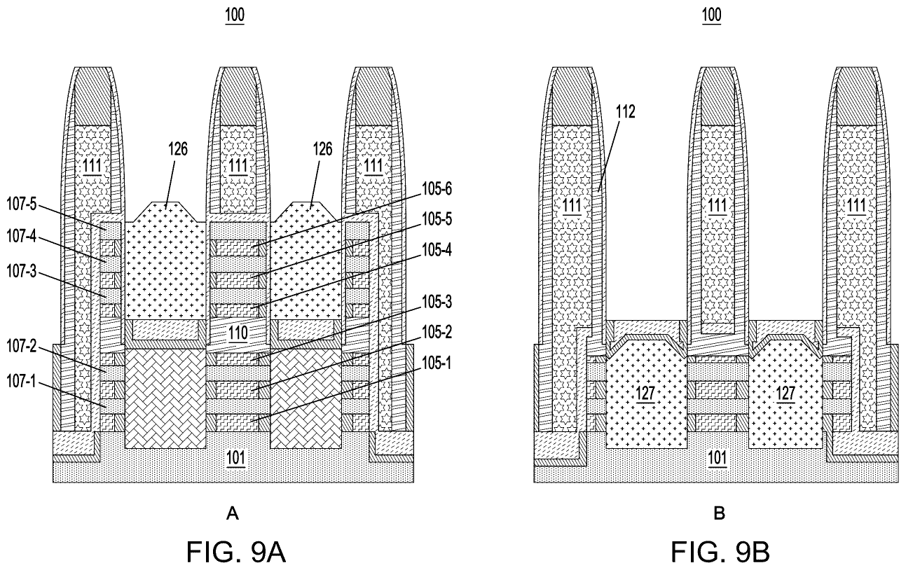

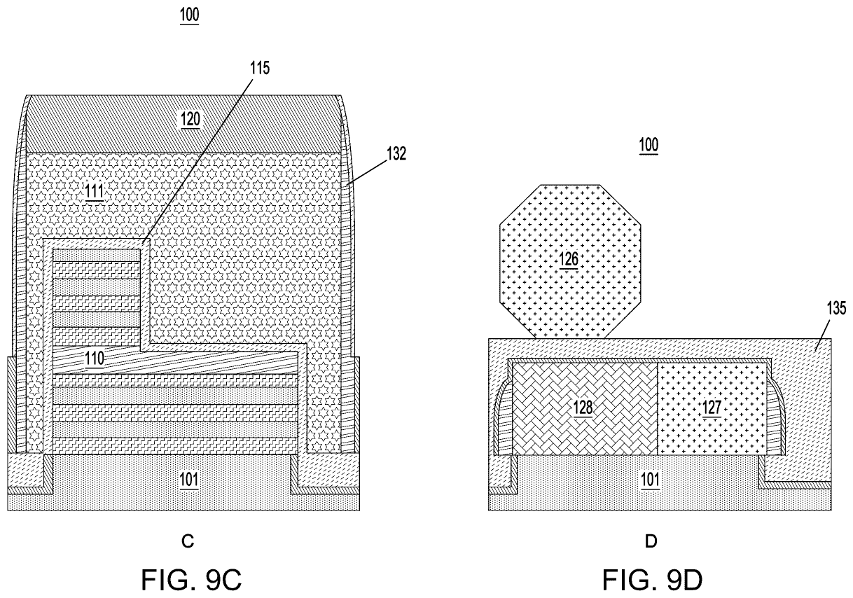

FIGS. 9A-9D depict cross-sectional views of the semiconductor structure 100 following formation of a top source/drain region 126, according to an illustrative embodiment. The top source/drain region 126 can be epitaxially grown from the exposed surfaces of the channel layers 107-3, 107-4, and 107-5, and isolated from sacrificial layers 105 by the inner spacers 113.

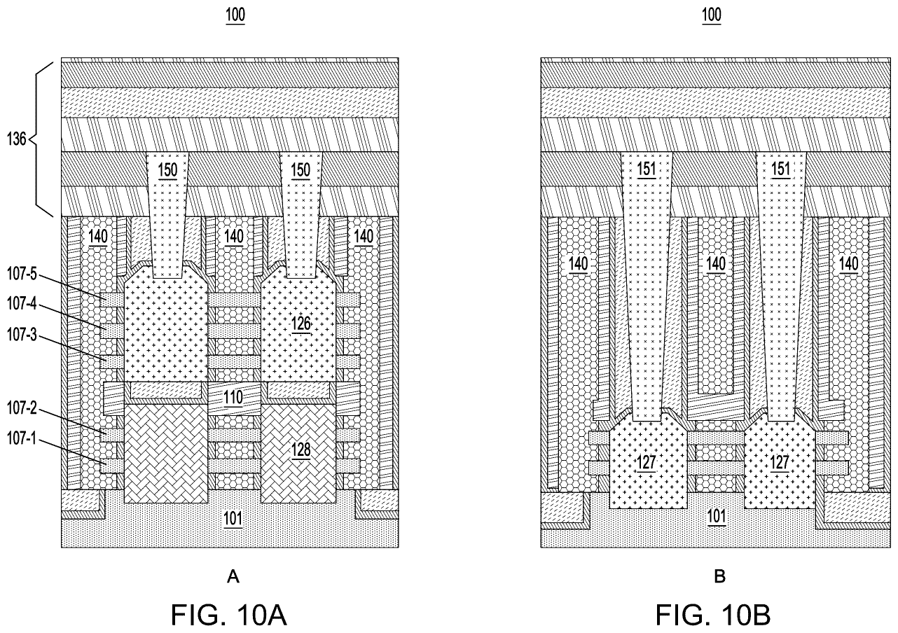

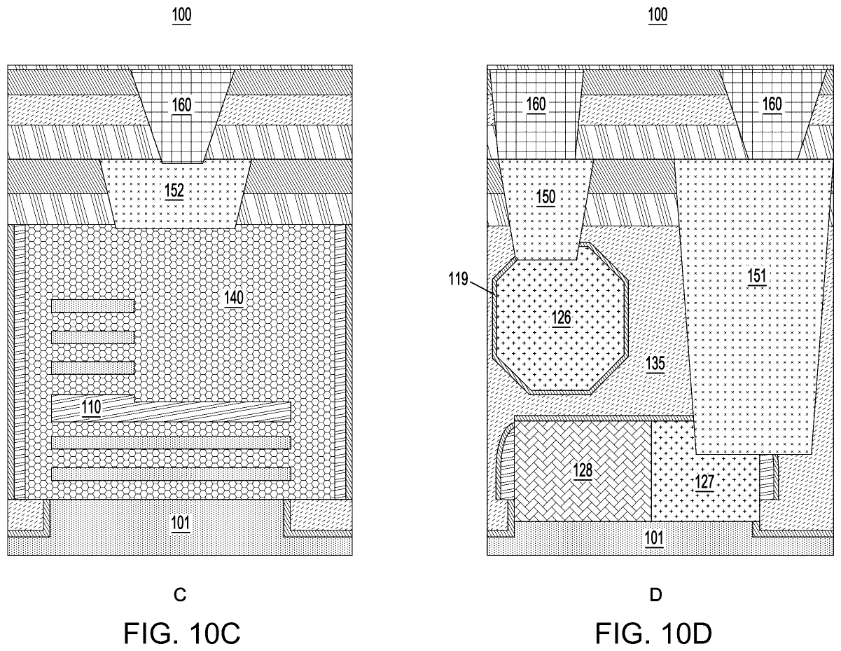

FIGS. 10A-10D depict cross-sectional views of the semiconductor structure 100 following further processing steps, according to an illustrative embodiment. The further processing steps can correspond to process of record (POR) steps for forming gate structures 140, additional ILD layers 136, frontside top source/drain contacts 150, frontside bottom source/drain contacts 151, a gate contact 152, and vias 160.

In illustrative embodiments, a liner layer 119 is formed using conformal deposition of a dielectric material that is deposited over exposed surfaces of the top source/drain region 126. The liner layer 119 can be formed using similar techniques and materials as described above with respect to the liner layer 108, for example.

Additional dielectric material is deposited so that the ILD layer 135 extends upwards to fill in the vacant areas between the stacks of channel layers 107 and surrounds the top source/drain region 126.

The HM layer 120, the dummy gate portions 111, and the sacrificial layers 105 can then be removed. In illustrative embodiments, a planarization process, such as CMP, is used to remove the HM layer 120 and/or portions of the gate spacers 112 to expose the dummy gate portions 111. In some embodiments, the HM layer 120 can be removed using a selective etching process, such as a dry etching process, a wet chemical etching process, or a combination of these etching processes.

The dummy gate portions 111 and the sacrificial layers 105 are selectively removed to create vacant areas. For example, the dummy gate portions 111 can be selectively removed using hot ammonia to remove a-Si, and the sacrificial layers 105 can be selectively removed with respect to the channel layers 107 using, for example, a dry HCl etch.

Following removal of the dummy gate portions 111 and the sacrificial layers 105, the channel layers 107 are suspended and the gate structures 140 are formed. The gate structures 140 each include a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

According to an embodiment, the gate structures 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

In some embodiments, a CMP process can be performed following the formation of the gate structure 140 to planarize the top surface of the semiconductor structure 100. One or more additional ILD layers 136 can then be formed on the top surface of the semiconductor structure 100 as part of the process for forming the frontside top source/drain contacts 150, the frontside bottom source/drain contacts 151, the gate contact 152, and the vias 160. The one or more additional ILD layers 136 can be formed using similar techniques and materials as described above with respect to ILD layer 135, for example.

The frontside top source/drain contacts 150 contact respective portions of the top source/drain region 126 as shown in FIGS. 10A and 10D, for example. In forming the frontside top source/drain contacts 150, openings are formed through portions of the ILD layer 135 and at least a portion of the additional ILD layers 136. The openings can be formed using one or more masks and removing portions of the ILD layer 135 and at least the portion of the additional ILD layers 136 using a dry etching process using a RIE or IBE process, a wet chemical etch process, or a combination of these etching processes. The openings expose portions of the top source/drain region 126 on which the frontside top source/drain contacts 150 are to be formed.

Metal layers are deposited in the openings to form the frontside top source/drain contacts 150. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the portions of the additional ILD layers 136.

The frontside bottom source/drain contacts 151 contact respective portions of the bottom source/drain region 127 as shown in FIGS. 10B and 10D, for example. The process and materials used for forming the frontside bottom source/drain contacts 151 are similar to those used for forming the frontside top source/drain contacts 150.

The gate contact 152 is formed through at least a portion of the additional ILD layers 136 to land on and contact a corresponding one of the gate structures 140. The process and materials used for forming the gate contact 152 are similar to those used for forming the frontside top source/drain contacts 150.

The vias 160 are formed in a portion of the additional ILD layers 136 above the frontside top source/drain contacts 150 and the frontside bottom source/drain contacts 151. The processes and materials used for forming the vias 160 are similar to those used for forming the frontside top source/drain contacts 150.

In some embodiments, the vias 160 can connect respective ones of the frontside top source/drain contacts 150 and the frontside bottom source/drain contacts 151 to one or more middle-of-line (MOL) metallization layers (not shown in FIGS. 10A-10D). The MOL metallization layers may electrically connect to various frontside back-end-of-line (BEOL) interconnect structures, for example. In an illustrative embodiment, a carrier wafer may be formed of materials similar to that of the semiconductor substrate 101 and may be formed over the frontside BEOL interconnects using a wafer bonding process, such as dielectric-to-dielectric bonding.

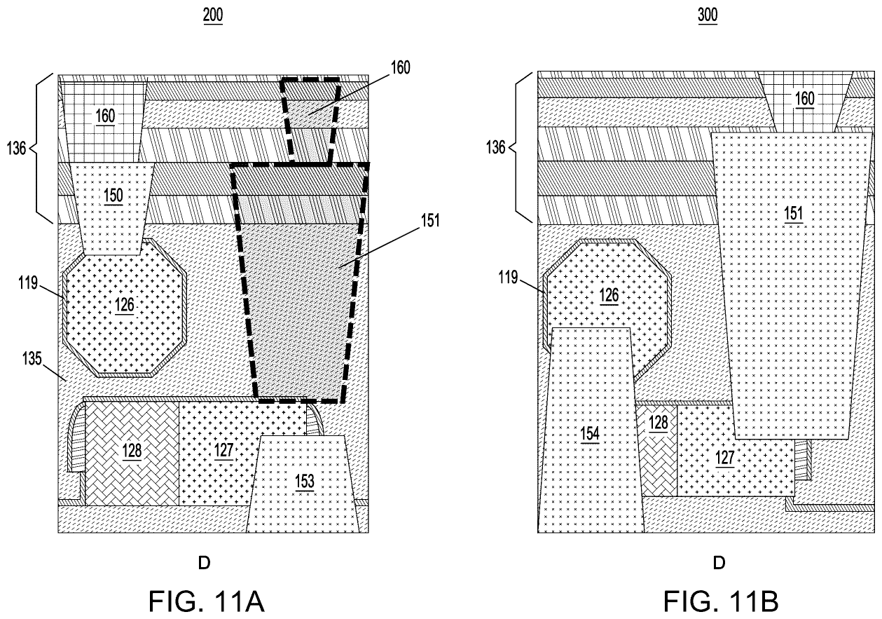

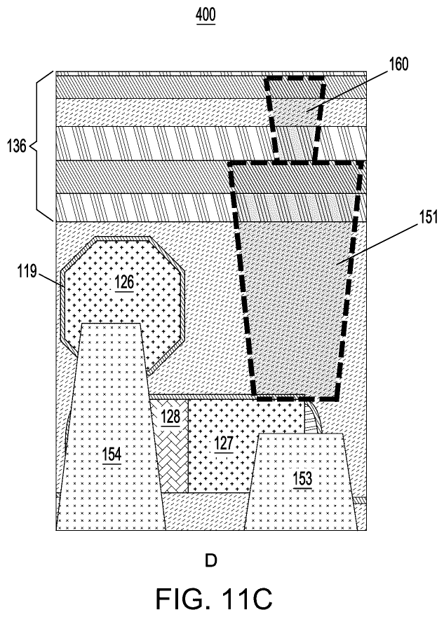

The arrangement of the frontside top source/drain contacts 150 and the frontside bottom source/drain contacts 151 shown in FIGS. 10A-10D is merely an example, and alternative arrangements are also possible, as discussed in more detail in conjunction with FIGS. 11A-11C.

FIGS. 11A-11C depict cross-sectional views corresponding to line D in FIG. 1 of alternative semiconductor structures 200, 300, and 400, according to illustrative embodiments. For example, the alternative semiconductor structure 200 shown in FIG. 11A includes a backside bottom source/drain contact 153 and a frontside top source drain contact 150. FIG. 11A also shows projections (as indicated by dashed lines) of a frontside bottom source/drain contact 151 and a projection of a corresponding one of the vias 160. The alternative semiconductor structure 300 shown in FIG. 11B includes a backside top source/drain contact 154 and a frontside bottom source/drain contact 151. The alternative semiconductor structure 400 shown in FIG. 11C includes a backside top source/drain contact 154 and a backside bottom source/drain contact 153. Accordingly, embodiments described herein enable source/drain connections to be connected from the frontside, the backside, or a combination of the frontside and the backside.

Formation of the backside top source/drain contacts 154 and/or the backside bottom source/drain contacts 153 shown in FIGS. 11A-11C can include removing the semiconductor substrate 101 and filling the resulting vacant areas with dielectric material (e.g., similar to the material of ILD layer 135, for example). Etching processes for removal of the semiconductor substrate 101 include, for example, one or more planarization processes (such as CMP), one or more etching process (e.g., one or more wet chemical etching processes), or a combination of such processes. The backside bottom source/drain contacts 153 and/or the backside top source/drain contacts 154 can then be formed using similar processes and materials used for forming the frontside top source/drain contacts 150, for example.

In some embodiments, the backside bottom source/drain contacts 153 and/or the backside top source/drain contacts 154 connect to various backside power delivery network (BSPDN) structures such as, but not necessarily limited to, interconnects in a power supply path from voltage regulator modules (VRMs) to circuits. The interconnects can comprise, for example, power and ground planes in circuit boards, cables, connectors, and capacitors associated with a power supply. Backside power delivery prevents BEOL routing congestion, resulting in power performance benefits. In some embodiments, the interconnects can alternatively or additionally be used for routing of signals, including power and/or clock signals as non-limiting examples.

It is to be appreciated that the backside top source/drain contacts 154 and the backside bottom source/drain contacts 153 shown in FIGS. 11A-11C can be positioned in any suitable position under the respective top source/drain region 126 and the bottom source/drain region 127. In some embodiments, one or more of the backside top source/drain contacts 154 and the backside bottom source/drain contacts 153 can be connected to one or more backside interconnects, which can include various BSPDN structures such as, but not necessarily limited to, interconnects in a power supply path from voltage regulator modules (VRMs) to circuits. The interconnects can comprise, for example, power and ground planes in circuit boards, cables, connectors, and capacitors associated with a power supply. Backside power delivery prevents BEOL routing congestion, resulting in power performance benefits.

In an illustrative embodiment, a semiconductor device includes a first plurality of channel layers and a first source/drain region and a second transistor device comprising a second plurality of channel layers and a second source/drain region, where the first plurality of channel layers are vertically stacked with the second plurality of channel layers and the first source/drain region is laterally offset from the second source/drain region.

In embodiments, the second plurality of channel layers may be wider than the first plurality of channel layers such that the first transistor device and the second transistor device form an L-shaped profile.

In embodiments, the first source/drain region may not vertically overlap with the second plurality of channel layers.

In embodiments, the first source/drain region may extend along a portion of the first plurality of channel layers.

In embodiments, a top surface of the first source/drain region may be below a level corresponding to a bottom surface of the second transistor device.

In embodiments, the semiconductor device may include one or more source/drain contacts connected to the first source/drain region.

In embodiments, the one or more source/drain contacts connected to the first source/drain region comprise at least one of one or more backside source/drain contacts and one or more frontside source/drain contacts.

In embodiments, the semiconductor device may include at least one gate region surrounding the first plurality of channel layers and the second plurality of channel layers.

In embodiments, the first transistor device may include one of an n-type transistor device and a p-type transistor device, and the second transistor device may include the other one of the n-type transistor device and the p-type transistor device.

In another illustrative embodiment, a semiconductor device includes an L-shaped stacked transistor architecture comprising a bottom transistor device having a bottom source/drain region and a top transistor device having a top source/drain region, where the bottom source/drain region is laterally offset from the top source/drain region.

In embodiments, the bottom transistor device may include a plurality of bottom channel layers and the top transistor device comprises a plurality of top channel layers, where the bottom source/drain region does not vertically overlap with the plurality of top channel layers.

In embodiments, the plurality of bottom channel layers may be wider than the plurality of top channel layers.

In embodiments, the semiconductor device includes one or more source/drain contacts connected to the bottom source/drain region.

In embodiments, the one or more source/drain contacts may include at least one of one or more backside source/drain contacts, and one or more frontside source/drain contacts.

In embodiments, a portion of the bottom source/drain region may extend along a stepped portion of the L-shaped stacked transistor architecture.

In embodiments, a top surface of the bottom source/drain region may be below a level corresponding to a bottom surface of the top transistor device.

In another exemplary embodiment, a method includes forming a first plurality of channel layers corresponding to a first transistor device and a second plurality of channel layers corresponding to a second transistor device, where the second plurality of channel layers is vertically stacked on the first plurality of channel layers, and where the first plurality of channel layers is wider than the second plurality of channel layers. The method includes forming a first source/drain region along at least a portion of the first plurality of channel layers, and forming a second source/drain region that is above and laterally offset from the first source/drain region.

In embodiments, the method may include forming at least one source/drain contact connected to the first source/drain region, where the at least one source/drain contact may include at least one of at least one backside source/drain contact and at least one frontside source/drain contact.

In embodiments, the first source/drain region may not vertically overlap with the second plurality of channel layers.

In embodiments, a top surface of the first source/drain region may be below a level corresponding to a bottom surface of the second transistor device.

Semiconductor devices and methods for forming the same in accordance with the above-described techniques can be employed in various applications, hardware, and/or electronic systems. Suitable hardware and systems for implementing embodiments of the present disclosure may include, but are not limited to, personal computers, communication networks, electronic commerce systems, portable communications devices (for example, cell and smart phones), solid-state media storage devices, functional circuitry, etc. Systems and hardware incorporating the semiconductor devices are contemplated embodiments of the present disclosure. Given the teachings provided herein, one of ordinary skill in the art will be able to contemplate other implementations and applications of embodiments of the present disclosure.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard; or (b) an end product. The end product can be any product that includes integrated circuit chips, ranging from toys and other low-end applications to advanced computer products having a display, a keyboard or other input device, and a central processor.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments described herein have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first transistor device comprising a first plurality of channel layers and a first source/drain region; and
a second transistor device comprising a second plurality of channel layers and a second source/drain region;
wherein the first plurality of channel layers are vertically stacked with the second plurality of channel layers and the first source/drain region is laterally offset from the second source/drain region.

2. The semiconductor device of claim 1, wherein the second plurality of channel layers is wider than the first plurality of channel layers such that the first transistor device and the second transistor device form an L-shaped profile.

3. The semiconductor device of claim 1, wherein the first source/drain region does not vertically overlap with the second plurality of channel layers.

4. The semiconductor device of claim 1, wherein the first source/drain region extends along a portion of the first plurality of channel layers.

5. The semiconductor device of claim 1, wherein a top surface of the first source/drain region is below a level corresponding to a bottom surface of the second transistor device.

6. The semiconductor device of claim 1, further comprising:
one or more source/drain contacts connected to the first source/drain region.

7. The semiconductor device of claim 6, wherein the one or more source/drain contacts connected to the first source/drain region comprise at least one of: one or more backside source/drain contacts and one or more frontside source/drain contacts.

8. The semiconductor device of claim 1, further comprising at least one gate region surrounding the first plurality of channel layers and the second plurality of channel layers.

9. The semiconductor device of claim 1, wherein the first transistor device comprises one of an n-type transistor device and a p-type transistor device, and the second transistor device comprises the other one of the n-type transistor device and the p-type transistor device.

10. A semiconductor device comprising:
an L-shaped stacked transistor architecture comprising a bottom transistor device having a bottom source/drain region and a top transistor device having a top source/drain region, wherein the bottom source/drain region is laterally offset from the top source/drain region.

11. The semiconductor device of claim 10, wherein:
the bottom transistor device comprises a plurality of bottom channel layers and the top transistor device comprises a plurality of top channel layers; and
the bottom source/drain region does not vertically overlap with the plurality of top channel layers.

12. The semiconductor device of claim 11, wherein the plurality of bottom channel layers is wider than the plurality of top channel layers.

13. The semiconductor device of claim 10, further comprising:
one or more source/drain contacts connected to the bottom source/drain region.

14. The semiconductor device of claim 13, wherein the one or more source/drain contacts comprise at least one of:
one or more backside source/drain contacts; and
one or more frontside source/drain contacts.

15. The semiconductor device of claim 10, wherein a portion of the bottom source/drain region extends along a stepped portion of the L-shaped stacked transistor architecture.

16. The semiconductor device of claim 10, wherein a top surface of the bottom source/drain region is below a level corresponding to a bottom surface of the top transistor device.

17. A method comprising:
forming a first plurality of channel layers corresponding to a first transistor device and a second plurality of channel layers corresponding to a second transistor device, wherein the second plurality of channel layers is vertically stacked on the first plurality of channel layers, and wherein the first plurality of channel layers is wider than the second plurality of channel layers;
forming a first source/drain region along at least a portion of the first plurality of channel layers; and
forming a second source/drain region that is above and laterally offset from the first source/drain region.

18. The method of claim 17, further comprising forming at least one source/drain contact connected to the first source/drain region, wherein the at least one source/drain contact comprises at least one of: at least one backside source/drain contact and at least one frontside source/drain contact.

19. The method of claim 17, wherein the first source/drain region does not vertically overlap with the second plurality of channel layers.

20. The method of claim 17, wherein a top surface of the first source/drain region is below a level corresponding to a bottom surface of the second transistor device.
